(19) United States
(12) Patent Application Publication
(10) Pub. No.: US 2021/0152771 A1
(43) Pub. Date: May 20, 2021

(54) BACKSIDE ILLUMINATED GLOBAL SHUTTER IMAGE SENSOR WITH AN ANALOG MEMORY CHARGE COUPLED DEVICE

(71) Applicant: SEMICONDUCTOR COMPONENTS INDUSTRIES, LLC, Phoenix, AZ (US)

(72) Inventor: Christopher PARKS, Pittsford, NY (US)

(73) Assignee: SEMICONDUCTOR COMPONENTS INDUSTRIES, LLC, Phoenix, AZ (US)

(21) Appl. No.: 16/688,322

(22) Filed: Nov. 19, 2019

(51) Int. Cl. H04N 5/3745; H01L 27/146; H04N 5/235

(52) U.S. Cl. CPC H04N 5/37452; H04N 5/2353; H01L 27/1464; H01L 27/14643

(57) ABSTRACT

A global shutter image sensor may include a charge coupled device to store charge while mitigating dark current. The image sensor may include a first semiconductor substrate with a photodiode, a floating diffusion region, a transfer transistor coupled between the photodiode and the floating diffusion region, and a source follower transistor having a gate coupled to the floating diffusion region. The image sensor may include a second semiconductor substrate with an analog memory charge coupled device. The charge coupled device may include an input gate that is coupled to the source follower transistor in the first substrate, a charge injector, at least one storage gate, and an output gate. The charge coupled device may store samples correlated to charge on the floating diffusion region in the first substrate. During readout, the samples may sequentially be transferred to an additional floating diffusion region in the second substrate using the output gate.

### BACKGROUND

This relates generally to image sensors, and more particularly, to global shutter image sensors.

Image sensors are commonly used in electronic devices such as cellular telephones, cameras, and computers to capture images. In a typical arrangement, an image sensor includes an array of image pixels arranged in pixel rows and pixel columns.

Typical image pixels contain a photodiode for generating charge in response to incident light. Image pixels may also include a charge storage region such as a storage capacitor for storing charge that is generated in the photodiode. Image sensors can operate using a global shutter or a rolling shutter scheme. In a global shutter, every pixel in the image sensor may simultaneously capture an image, whereas in a rolling shutter each row of pixels may sequentially capture an image. Global shutter image sensors may require a charge storage region to store charge that is subsequently read out in a row-by-row manner.

In backside illuminated (BSI) image sensors, it may be difficult to shield a charge storage region for implementing global shutter functionality from incident light. The charge storage region may also be susceptible to high levels of dark current.

It would therefore be desirable to be able to provide improved backside illuminated global shutter image sensors.

### BRIEF DESCRIPTION OF THE DRAWINGS

FIG. 1 is a diagram of an illustrative electronic device having an image sensor in accordance with an embodiment.

FIG. 2 is a diagram of an illustrative pixel array and associated readout circuitry for reading out image signals in an image sensor in accordance with an embodiment.

FIG. 3 is a perspective view of an illustrative image sensor with multiple chips and conductive bonds between the upper chip and middle chip in accordance with an embodiment.

FIG. 4 is a circuit diagram of an illustrative image sensor having pixel circuitry coupled to an analog memory charge coupled device in accordance with an embodiment.

FIG. 5 is a series of potential diagrams showing operation of the analog memory charge coupled device of FIG. 4 during a sampling phase in accordance with an embodiment.

FIG. 6 is a timing diagram showing operation of the image sensor of FIG. 4 during a sampling phase in accordance with an embodiment.

FIG. 7 is a series of potential diagrams showing operation of the analog memory charge coupled device of FIG. 4 during a readout phase in accordance with an embodiment.

FIG. 8 is a circuit diagram of an illustrative image sensor having pixel circuitry coupled to a four-stage analog memory charge coupled device in accordance with an embodiment.

FIG. 9 is a circuit diagram of an illustrative image sensor having two pixel circuits that share an analog memory charge coupled device in accordance with an embodiment.

FIG. 10 is a top view of an illustrative analog memory charge coupled device with multiple injection points for respective pixel circuits along its length in accordance with an embodiment.

FIG. 11 is a cross-sectional side view of an illustrative analog memory charge coupled device showing how a supplemental gate may be interposed between the first storage gate and the input gate to mitigate dark current in accordance with an embodiment.

### DETAILED DESCRIPTION

Embodiments of the present invention relate to image sensors. It will be recognized by one skilled in the art that the present exemplary embodiments may be practiced without some or all of these specific details. In other instances, well-known operations have not been described in detail in order not to unnecessarily obscure the present embodiments.

Electronic devices such as digital cameras, computers, cellular telephones, and other electronic devices may include image sensors that gather incoming light to capture an image. The image sensors may include arrays of pixels. The pixels in the image sensors may include photosensitive elements such as photodiodes that convert the incoming light into image signals. Image sensors may have any number of pixels (e.g., hundreds or thousands or more). A typical image sensor may, for example, have hundreds of thousands or millions of pixels (e.g., megapixels). Image sensors may include control circuitry such as circuitry for operating the pixels and readout circuitry for reading out image signals corresponding to the electric charge generated by the photosensitive elements.

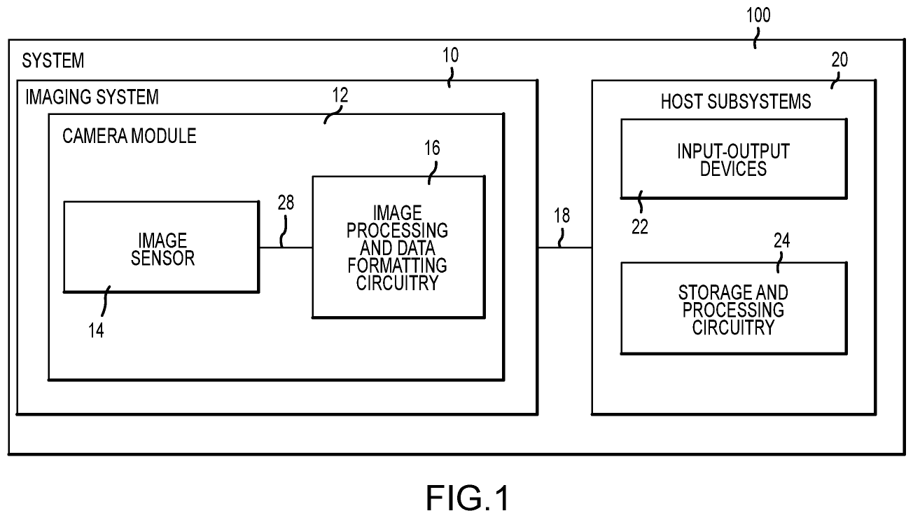

FIG. 1 is a diagram of an illustrative imaging and response system including an imaging system that uses an image sensor to capture images. System 100 of FIG. 1 may be an electronic device such as a camera, a cellular telephone, a video camera, or other electronic device that captures digital image data, may be a vehicle safety system (e.g., an active braking system or other vehicle safety system), or may be a surveillance system.

As shown in FIG. 1, system 100 may include an imaging system such as imaging system 10 and host subsystems such as host subsystem 20. Imaging system 10 may include camera module 12. Camera module 12 may include one or more image sensors 14 and one or more lenses.

Each image sensor in camera module 12 may be identical or there may be different types of image sensors in a given image sensor array integrated circuit. During image capture operations, each lens may focus light onto an associated image sensor 14. Image sensor 14 may include photosensitive elements (i.e., pixels) that convert the light into digital data. Image sensors may have any number of pixels (e.g., hundreds, thousands, millions, or more). A typical image sensor may, for example, have millions of pixels (e.g., megapixels). As examples, image sensor 14 may include bias circuitry (e.g., source follower load circuits), sample and hold circuitry, correlated double sampling (CDS) circuitry, amplifier circuitry, analog-to-digital converter circuitry, data output circuitry, memory (e.g., buffer circuitry), address circuitry, etc.

Still and video image data from camera sensor 14 may be provided to image processing and data formatting circuitry 16 via path 28. Image processing and data formatting circuitry 16 may be used to perform image processing functions such as data formatting, adjusting white balance and exposure, implementing video image stabilization, face detection, etc. Image processing and data formatting circuitry 16 may also be used to compress raw camera image files if desired (e.g., to Joint Photographic Experts Group or JPEG format). In a typical arrangement, which is sometimes referred to as a system on chip (SOC) arrangement, image sensor 14 and image processing and data formatting circuitry 16 are implemented on a common semiconductor substrate (e.g., a common silicon image sensor integrated circuit die). If desired, camera sensor 14 and image processing circuitry 16 may be formed on separate semiconductor substrates. For example, camera sensor 14 and image processing circuitry 16 may be formed on separate substrates that have been stacked.

Imaging system 10 (e.g., image processing and data formatting circuitry 16) may convey acquired image data to host subsystem 20 over path 18. Host subsystem 20 may include processing software for detecting objects in images, detecting motion of objects between image frames, determining distances to objects in images, filtering or otherwise processing images provided by imaging system 10.

If desired, system 100 may provide a user with numerous high-level functions. In a computer or advanced cellular telephone, for example, a user may be provided with the ability to run user applications. To implement these functions, host subsystem 20 of system 100 may have input-output devices 22 such as buttons, keypads, touch-sensitive areas, input-output ports, joysticks, and displays and storage and processing circuitry 24. Storage and processing circuitry 24 may include volatile and nonvolatile memory (e.g., random-access memory, flash memory, hard drives, solid-state drives, etc.). Storage and processing circuitry 24 may also include microprocessors, microcontrollers, digital signal processors, application specific integrated circuits, etc.

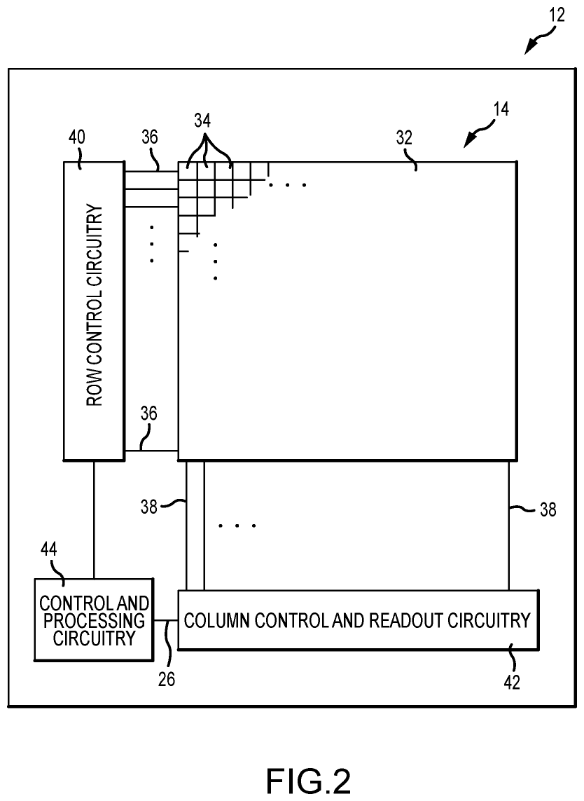

An example of an arrangement for camera module 12 of FIG. 1 is shown in FIG. 2. As shown in FIG. 2, camera module 12 includes image sensor 14 and control and processing circuitry 44. Control and processing circuitry 44 may correspond to image processing and data formatting circuitry 16 in FIG. 1. Image sensor 14 may include a pixel array such as array 32 of pixels 34 (sometimes referred to herein as image sensor pixels, imaging pixels, or image pixels 34) and may also include control circuitry 40 and 42. Control and processing circuitry 44 may be coupled to row control circuitry 40 and may be coupled to column control and readout circuitry 42 via data path 26. Row control circuitry 40 may receive row addresses from control and processing circuitry 44 and may supply corresponding row control signals to image pixels 34 over control paths 36 (e.g., dual conversion gain control signals, pixel reset control signals, charge transfer control signals, blooming control signals, row select control signals, or any other desired pixel control signals). Column control and readout circuitry 42 may be coupled to the columns of pixel array 32 via one or more conductive lines such as column lines 38. Column lines 38 may be coupled to each column of image pixels 34 in image pixel array 32 (e.g., each column of pixels may be coupled to a corresponding column line 38). Column lines 38 may be used for reading out image signals from image pixels 34 and for supplying bias signals (e.g., bias currents or bias voltages) to image pixels 34. During image pixel readout operations, a pixel row in image pixel array 32 may be selected using row control circuitry 40 and image data associated with image pixels 34 of that pixel row may be read out by column control and readout circuitry 42 on column lines 38.

Column control and readout circuitry 42 may include column circuitry such as column amplifiers for amplifying signals read out from array 32, sample and hold circuitry for sampling and storing signals read out from array 32, analog-to-digital converter circuits for converting read out analog signals to corresponding digital signals, and column memory for storing the read out signals and any other desired data. Column control and readout circuitry 42 may output digital pixel values to control and processing circuitry 44 over line 26.

Array 32 may have any number of rows and columns. In general, the size of array 32 and the number of rows and columns in array 32 will depend on the particular implementation of image sensor 14. While rows and columns are generally described herein as being horizontal and vertical, respectively, rows and columns may refer to any grid-like structure (e.g., features described herein as rows may be arranged vertically and features described herein as columns may be arranged horizontally).

Pixel array 32 may be provided with a color filter array having multiple color filter elements which allows a single image sensor to sample light of different colors. As an example, image sensor pixels such as the image pixels in array 32 may be provided with a color filter array which allows a single image sensor to sample red, green, and blue (RGB) light using corresponding red, green, and blue image sensor pixels arranged in a Bayer mosaic pattern. The Bayer mosaic pattern consists of a repeating unit cell of two-by-two image pixels, with two green image pixels diagonally opposite one another and adjacent to a red image pixel diagonally opposite to a blue image pixel. In another suitable example, the green pixels in a Bayer pattern are replaced by broadband image pixels having broadband color filter elements (e.g., clear color filter elements, yellow color filter elements, etc.). These examples are merely illustrative and, in general, color filter elements of any desired color and in any desired pattern may be formed over any desired number of image pixels 34.

If desired, array 32 may be part of a stacked-die arrangement in which pixels 34 of array 32 are split between two or more stacked substrates. In such an arrangement, each of the pixels 34 in the array 32 may be split between the two dies at any desired node within the pixel. As an example, a node such as the floating diffusion node may be formed across two dies. Pixel circuitry that includes the photodiode and the circuitry coupled between the photodiode and the desired node (such as the floating diffusion node, in the present example) may be formed on a first die, and the remaining pixel circuitry may be formed on a second die. The desired node may be formed on (i.e., as a part of) a coupling structure (such as a conductive pad, a micro-pad, a conductive interconnect structure, a conductive via, etc.) that connects the two dies. Before the two dies are bonded, the coupling structure may have a first portion on the first die and may have a second portion on the second die. The first die and the second die may be bonded to each other such that first portion of the coupling structure and the second portion of the coupling structure are bonded together and are electrically coupled. If desired, the first and second portions of the coupling structure may be compression bonded to each other. However, this is merely illustrative. If desired, the first and second portions of the coupling structures formed on the respective first and second dies may be bonded together using any metal-to-metal bonding technique, such as soldering or welding.

As mentioned above, the desired node in the pixel circuit that is split across the two dies may be a floating diffusion node. Alternatively, the desired node in the pixel circuit that is split across the two dies may be the node between a floating diffusion region and the gate of a source follower transistor (i.e., the floating diffusion node may be formed on the first die on which the photodiode is formed, while the coupling structure may connect the floating diffusion node to the source follower transistor on the second die), the node between a floating diffusion region and a source-drain node of a transfer transistor (i.e., the floating diffusion node may be formed on the second die on which the photodiode is not located), the node between a source-drain node of a source follower transistor and a row select transistor, or any other desired node of the pixel circuit.

In general, array 32, row control circuitry 40, column control and readout circuitry 42, and control and processing circuitry 44 may be split between two or more stacked substrates. In one example, array 32 may be formed in a first substrate and row control circuitry 40, column control and readout circuitry 42, and control and processing circuitry 44 may be formed in a second substrate. In another example, array 32 may be split between first and second substrates (using one of the pixel splitting schemes described above) and row control circuitry 40, column control and readout circuitry 42, and control and processing circuitry 44 may be formed in a third substrate.

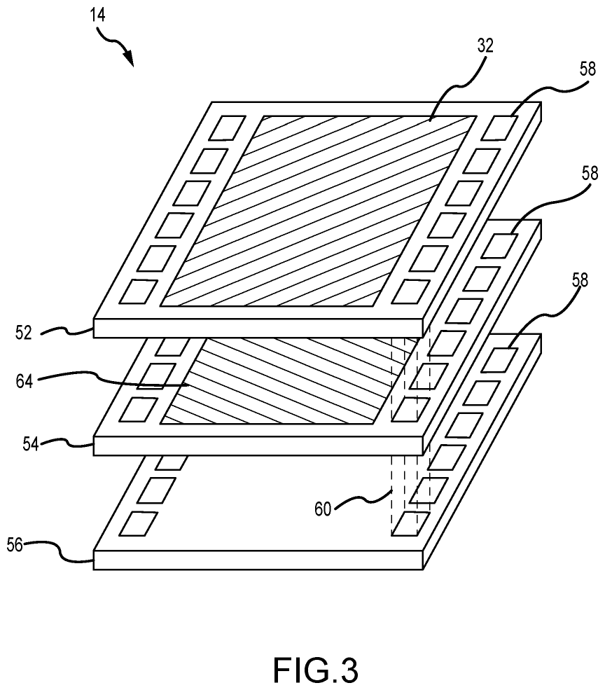

An example of an image sensor split between two or more substrate layers is shown in FIG. 3. Image sensor 14 may be formed with one or more substrate layers. The substrate layers may be layers of semiconductor material such as silicon. The substrate layers may be connected using metal interconnects. In FIG. 3, substrates 52, 54, and 56 are used to form image sensor 14. Substrates 52, 54 and 56 may sometimes be referred to as chips. Upper chip 52 may contain photodiodes in pixel array 32. Floating diffusion regions and storage gates may also be included in upper chip 52 and/or middle chip 54. To ensure that there is adequate room for the photodiodes in upper chip 52, much of the pixel circuitry for the pixels may be formed in middle chip 54 and lower chip 56. Middle chip 54 may include an amplifier, charge storage region, reset transistor, and/or a source follower, for example.

Middle chip 54 may be bonded to upper chip 52 with an interconnect layer at every pixel or an interconnect for a group of pixels (e.g., two pixels, three pixels, more than three pixels, etc.). Bonding each pixel in upper chip 52 to corresponding circuitry 64 in middle chip 54 may be referred to as hybrid bonding. Middle chip 54 and lower chip 56 may not be coupled with hybrid bonding. Only peripheral electrical contact pads 58 of each chip may be bonded together (e.g., chip-to-chip connections 60). Each chip in image sensor 14 may include relevant circuitry. The upper chip may contain pinned photodiodes, floating diffusion regions, reset transistors, and a first source follower transistor. The middle chip may include an additional source follower transistor, one or more charge storage regions, one or more capacitors, and additional transistors. The bottom chip may include one or more of clock generating circuits, pixel addressing circuits, signal processing circuits such as the CDS circuits, analog to digital converter circuits, digital image processing circuits, and system interface circuits.

The example of FIG. 3 of image sensor 14 having three substrates is merely illustrative. If desired, the image sensor may be formed using a single substrate, using two substrates, or using more than three substrates. Each pair of adjacent substrates may optionally be bonded using hybrid bonding (e.g., a per-pixel metal interconnect layer) or may be bonded only at the periphery of the substrates.

Image sensor 14 may have global shutter capabilities and may be a backside illuminated (BSI) image sensor. During global shutter operations, every pixel in the image sensor may simultaneously capture an image, then the signals from the pixels are read out row-by-row. To enable global shutter capabilities, a storage node may be incorporated into the imaging pixel that allows storage of the signals. However, in backside illuminated image sensors (where the image sensor wiring is positioned below the semiconductor substrate with the photodiode), it may be difficult to prevent light leakage from compromising the charge stored in the pixel. To shield the charge storage region from light leakage, the charge storage region may be implemented as a storage capacitor in the second substrate (that is connected to the first substrate, that includes a photodiode, by a conductive interconnect layer). However, the storage capacitor may be coupled to a diffusion region in the second substrate and may therefore have a high dark current (particularly at high temperatures). The high dark current increases noise within the image sensor, reducing image sensor performance.

To provide global shutter functionality while reducing noise, a charge coupled device (CCD) may be used as a storage device for the image sensor pixels. The charge coupled device serves as analog memory storage for pixel reset (e.g., SHR) and sample (e.g., SHS) voltages.

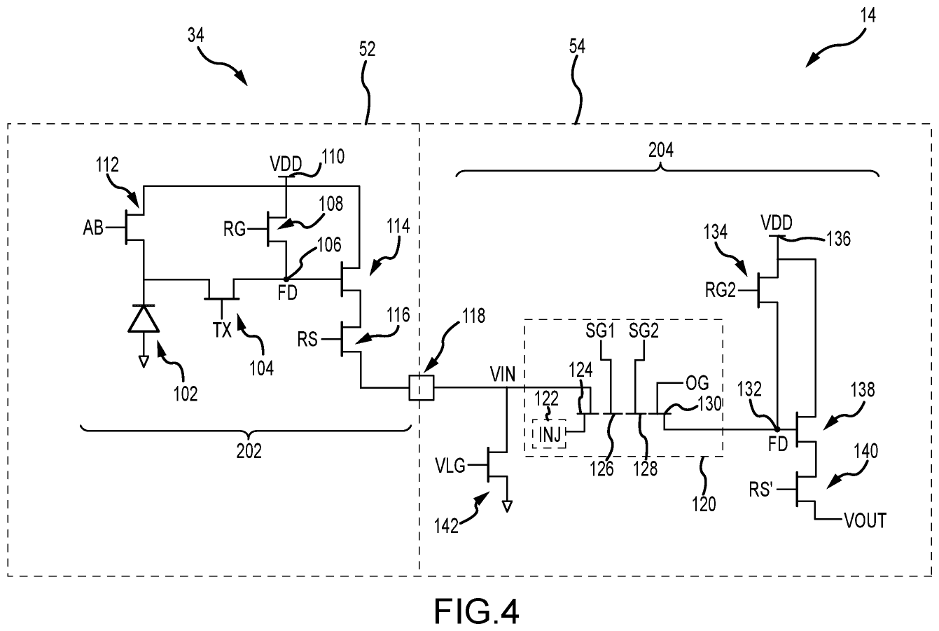

FIG. 4 is a circuit diagram of an illustrative imaging pixel 34. As shown, pixel 34 may include a photosensitive element 102 (e.g., a photodiode). Photosensitive element 102 has a first terminal that is coupled to ground. The second terminal of photosensitive element 102 is coupled to transfer transistor 104 and anti-blooming transistor 112. Transfer transistor 104 is coupled to floating diffusion region 106 (FD). A reset transistor 108 may be coupled between floating diffusion region FD and voltage supply 110. Voltage supply 110 may provide a voltage VDD. Anti-blooming transistor 112 is coupled between photodiode 102 and voltage supply 110. Floating diffusion region 106 may be a doped semiconductor region (e.g., a region in a silicon substrate that is doped by ion implantation, impurity diffusion, or other doping process).

Source follower transistor 114 has a gate terminal coupled to floating diffusion region FD and a first terminal of reset transistor 108. Source follower transistor 114 also has a first source-drain terminal coupled to voltage supply 110. In this application, each transistor is illustrated as having three terminals: a source, a drain, and a gate. The source and drain terminals of each transistor may be changed depending on how the transistors are biased and the type of transistor used. For the sake of simplicity, the source and drain terminals are referred to herein as source-drain terminals or simply terminals. A second source-drain terminal of source follower transistor 114 is coupled to sampling transistor 116 (sometimes referred to as row select transistor 116).

In the example of FIG. 4, row select transistor 116 is interposed between source follower transistor 114 and conductive interconnect layer 118 (sometimes referred to as interconnect layer 118, metal interconnect layer 118, etc.). Interconnect layer 118 may be formed from a conductive material such as metal (e.g., copper). In certain embodiments, the interconnect layer may include solder. The interconnect layer may also be a through silicon via (TSV). Interconnect layer 118 may couple substrate 52 to substrate 54 (e.g., a hybrid bond as discussed in connection with FIG. 3). Photodiode 102, floating diffusion region 106, bias voltage supply terminal 110, and transistors 104, 108, 112, 114, and 116 may all be formed in substrate 52.

A gate terminal of transfer transistor 104 receives control signal TX. A gate terminal of reset transistor 108 receives control signal RG. A gate terminal of row select transistor 116 receives control signal RS. A gate terminal of anti-blooming transistor 112 receives control signal AB. Control signals TX, RG, RS, and AB may be provided by row control circuitry (e.g., row control circuitry 40 in FIG. 2) over control paths (e.g., control paths 36 in FIG. 2).

As shown in FIG. 4, photodiode 102, floating diffusion region 106, bias voltage supply terminal 110, and transistors 104, 108, 112, 114, and 116 may sometimes collectively be referred to as pixel circuitry 202.

Conductive interconnect layer 118 may be coupled to an analog memory charge coupled device (CCD) 120 (sometimes referred to as CCD 120, memory CCD 120 etc.). CCD 120 may include a charge injector 122, an input gate 124, a first storage gate 126, a second storage gate 128, and an output gate 130. Charge injector 122 may be formed from an n-type diffusion region in substrate 54 that is coupled to a bias voltage (INJ). Input gate 124 may be coupled to conductive interconnect layer 118 and may receive an input voltage (VIN) that is proportional to the voltage on floating diffusion region 106 in substrate 52 (when row select transistor 116 is asserted). Storage gates 126 and 128 may be used to shift charge within the CCD. Output gate 130 may be used to selectively transfer charge from the CCD to floating diffusion region 132 in substrate 54. The CCD gates may include doped portions (e.g., boron-doped portions) underneath the gates that set the potential profiles of the gates.

A reset transistor 134 may be coupled between floating diffusion region 132 (FD) and voltage supply 136. Voltage supply 134 may provide a voltage VDD (that may the same or different from the voltage provided by supply 110). Floating diffusion region 132 may be a doped semiconductor region (e.g., a region in a silicon substrate that is doped by ion implantation, impurity diffusion, or other doping process). Source follower transistor 138 has a gate terminal coupled to floating diffusion region 132 and a first terminal of reset transistor 134. Source follower transistor 138 also has a first source-drain terminal coupled to voltage supply 136. A second source-drain terminal of source follower transistor 138 is coupled to sampling transistor 140 (sometimes referred to as row select transistor 140). Transistor 142 (which is used to provide a bias current) is also coupled to the conductive interconnect layer 118.

A gate terminal of reset transistor 134 receives control signal RG2. A gate terminal of row select transistor 140 receives control signal RS′. Storage gate 126 receives control signal SG1. Storage gate 128 receives control signal SG2. Output gate 130 receives control signal OG. Control signals RG2, SG1, SG2, OG, and RS′ may be provided by row control circuitry (e.g., row control circuitry 40 in FIG. 2) over control paths (e.g., control paths 36 in FIG. 2).

Transistor 142, CCD 120 (including charge injector 122, input gate 124, storage gates 126 and 128, and output gate 130), floating diffusion region 132, reset transistor 134, power supply terminal 136, source follower transistor 138, and row select transistor 140 may all be formed in substrate 54 as shown in FIG. 4. Transistor 142, CCD 120 (including charge injector 122, input gate 124, storage gates 126 and 128, and output gate 130), floating diffusion region 132, reset transistor 134, power supply terminal 136, source follower transistor 138, and row select transistor 140 may collectively be referred to as storage and readout circuitry 204. The distinction between pixel circuitry 202 and storage and readout circuitry 204 is merely illustrative. Other nomenclature may be used if desired. For example, pixel circuitry 202 may instead be referred to as a pixel (e.g., pixel 34 or pixel 202) that is coupled to a respective storage and readout circuit 204.

During operation of pixel 34, charge may accumulate in photodiode 102 in response to incident light. The amount of charge accumulated in the photodiode may be proportional to the intensity of the incident light received and the exposure time of the imaging pixel. Before the conclusion of the integration time of the pixel, the floating diffusion region 106 may be reset to a reset voltage by asserting reset transistor 108. Then, charge from the photodiode may be transferred to floating diffusion region 106 by asserting transfer transistor 104.

The pixel of FIG. 4 may implement double sampling techniques. In double sampling, a reset value and a signal value are obtained during readout. The reset value may then be subtracted from the signal value during subsequent processing to help correct for noise. The double sampling may be correlated double sampling (in which the reset value is sampled before the signal value) or uncorrelated double sampling (in which the reset value is sampled after the signal value is sampled). Any of the samples taken during operation of the pixel of FIG. 4 may use correlated double sampling or uncorrelated double sampling.

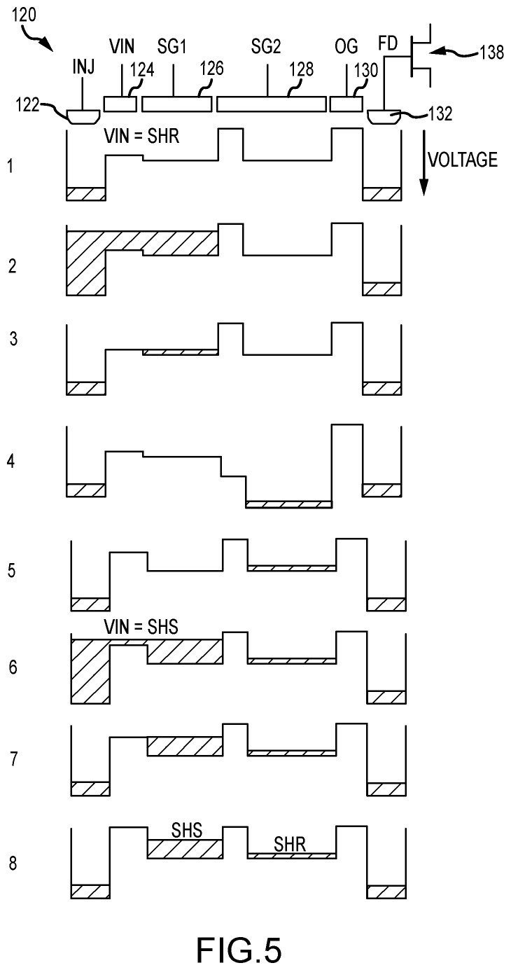

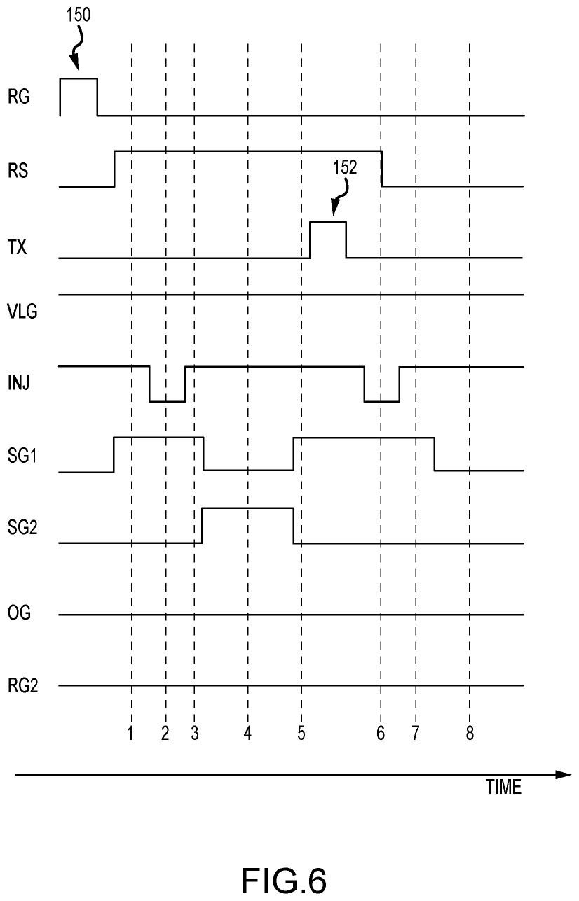

The reset and signal values may be stored in CCD 120 (as will be discussed in greater detail in connection with FIGS. 5 and 6). Storing the reset and signal values in CCD 120 may be performed globally (e.g., simultaneously for each imaging pixel in the image sensor). When the reset and signal values are ready to be read from CCD 120 (e.g., in a row-by-row manner), the reset and signal values may be transferred to and read from floating diffusion 132. Correlated double sampling may also be performed at this stage to mitigate noise.

FIG. 5 is a potential diagram of CCD 120 at eight different times that illustrates the operation of CCD 120. FIG. 6 is a timing diagram showing illustrative operation of the CCD 120 and other portions of the imaging pixel. Potential diagrams 1-8 in FIG. 5 correspond to times 1-8 depicted on the timing diagram of FIG. 6.

As shown in FIG. 6, the reset transistor may be asserted at assertion 150. Asserting the reset transistor resets floating diffusion region 106 in substrate 52 to a reset voltage. At time 1 in FIG. 6, row select transistor 116 is asserted (by raising RS) and control signal SG1 is raised high. Because row select transistor 116 is asserted, the voltage VIN at CCD input gate 124 is correlated to the reset voltage of the floating diffusion region 106 (e.g., the reset signal).

At time 2 in FIG. 6, the bias voltage (INJ) provided to charge injector 122 is lowered. This fills the region under gate 126 with charge, as shown by potential diagram 2 in FIG. 5. The bias voltage provided to charge injector 122 is then returned to its higher level at time 3. As shown by potential diagram 3 in FIG. 5, this causes excess charge to drain, except for what is contained under gate 126. The input voltage VIN on gate 124 sets the potential barrier between storage gate 126 and charge injector 122. Therefore, the amount of charge accumulated under storage gate 126 at time 3 is correlated to the input voltage VIN (which in this case is correlated with the reset signal). Therefore, the charge under storage gate 126 at time 3 is correlated to the reset voltage of floating diffusion 106.

At time 4, SG1 is lowered and SG2 is raised. As shown by potential diagram 4 in FIG. 5, this cases the charge under storage gate 126 to be transferred to the region under storage gate 128. Storage gate 126 is therefore empty and available to receive a new charge sample.

At time 5, SG1 is returned to a high level and SG2 is returned to a low level. Then, charge is transferred from photodiode 102 to floating diffusion region 106 by raising control signal TX (e.g., at assertion 152) and asserting transfer transistor 104. This causes a corresponding drop in the voltage at floating diffusion region 106. Accordingly, voltage VIN drops to a different level.

At time 6, the bias voltage (INJ) provided to charge injector 122 is lowered. This fills the region under gate 126 with charge, as shown by potential diagram 6 in FIG. 5. The bias voltage provided to charge injector 122 is then returned to its higher level at time 7. As shown by potential diagram 7 in FIG. 5, this causes excess charge to drain, except for what is contained under gate 126. The input voltage VIN on gate 124 sets the potential barrier between storage gate 126 and charge injector 122. Therefore, the amount of charge accumulated under storage gate 126 at time 7 is correlated to the input voltage VIN (which at this time is correlated with the sample signal). Therefore, the charge under storage gate 126 at time 7 is correlated to the sample voltage of floating diffusion 106.

At time 8, RS, SG1, TX, and SG2 may all be low. As shown by potential diagram 8 in FIG. 5, the charge accumulated under storage gate 128 is correlated to a reset signal from the floating diffusion region 106 (e.g., SHR) whereas the charge accumulated under storage gate 126 is correlated to a sample signal from the floating diffusion region 106 (e.g., SHS).

The n-type diffusion regions that are used to form charge injector 122 and floating diffusion region 132 may be susceptible to dark current. However, as shown by potential diagram 8 in FIG. 5, the samples (SHS and SHR) are isolated from these diffusion regions (e.g., by the input and output gates). Therefore, dark current from regions 122 and 132 does not reach the SHS and SHR samples. To prevent dark current, storage gates 126 and 128 may be held at a low voltage while charge is stored in the gates (e.g., −1 V, a voltage less than 0 V, a voltage less than −0.5 V, a voltage between −0.5 and −1.5 V, etc.). This negative voltage suppresses dark current, further insulating the SHS and SHR samples from dark current.

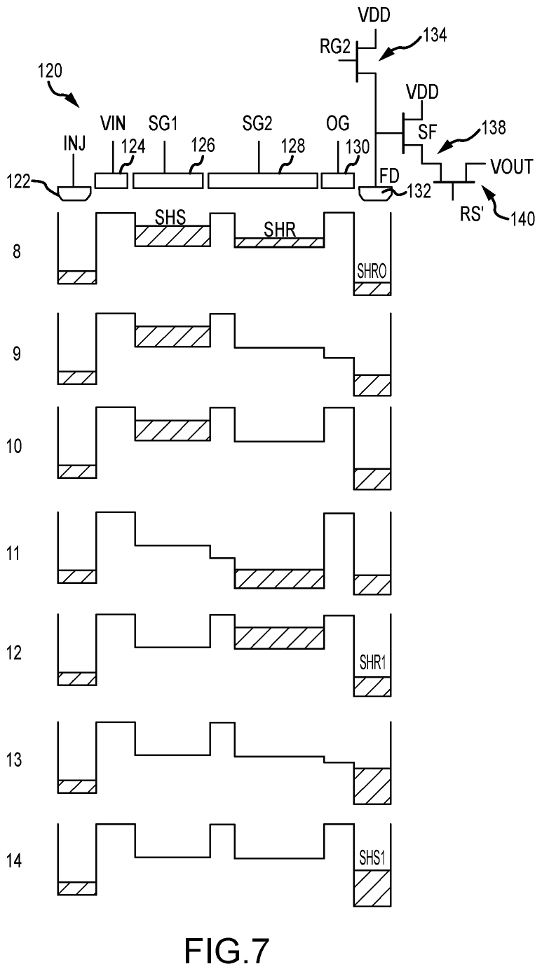

The sampling sequence of FIGS. 5 and 6 may be performed globally (e.g., simultaneously for all of the imaging pixels). The samples may then be read out in a row-by-row manner. The readout sequence is shown in FIG. 7. FIG. 7 is a potential diagram of CCD 120 at seven different times that illustrates the operation of CCD 120 during the readout sequence.

FIG. 7 begins with potential diagram 8, which is the same as potential diagram 8 in FIG. 5 (e.g., with an SHR sample under storage gate 128 and an SHS sample under storage gate 126).

Because the SHR and SHS samples are transferred to and ultimately read from floating diffusion 132, an additional reset sample is obtained as shown in potential diagram 8 in FIG. 7. Floating diffusion region 132 may be reset (e.g., by asserting transistor 134) and the reset voltage may be sampled (e.g., by determining VOUT while row select transistor 140 is asserted). This reset sample may be referred to as SHR0.

To read out the samples, the control signal OG is raised high, as shown in potential diagram 9. This causes the SHR sample to be transferred to the floating diffusion region. Then, as shown by potential diagram 10, the control signal OG may be returned to a lower level. Next, the SHS sample may be transferred from storage gate 126 to storage gate 128 (e.g., by toggling SG1 and SG2 as shown in potential diagrams 11 and 12).

After the SHR sample is transferred to floating diffusion region 132, the voltage of the floating diffusion region 132 is equal to a sum of the reset voltage of the floating diffusion 132 (SHR0) and the SHR sample transferred to the floating diffusion region. This combination (which may be referred to as SHR1) may be sampled (e.g., by determining VOUT). SHR0 may then be subtracted from SHR1 to determine SHR.

To read out the SHS sample, the control signal OG is raised high, as shown in potential diagram 13. This causes the SHS sample to be transferred to the floating diffusion region. Then, as shown by potential diagram 14, the control signal OG may be returned to a lower level. After the SHS sample is transferred to floating diffusion region 132, the voltage of the floating diffusion region 132 is equal to the sum of the reset voltage of the floating diffusion 132 (SHR0) and the SHR and SHS samples transferred to the floating diffusion region. This combination (which may be referred to as SHS1) may be sampled (e.g., by determining VOUT). SHR1 may then be subtracted from SHS1 to determine SHS. Finally, SHR may be subtracted from SHS to determine how much charge was originally transferred out of the photodiode.

It should be noted that the amount of charge stored in the CCD (e.g., SHS and SHR at potential diagram 8 in FIG. 5) is not necessarily at a 1 to 1 ratio with the amount of charge originally in the photodiode. The ratio may be tuned to be any desired value greater than 1 or less than 1 (e.g., using the size of the storage gate 126 and storage gate 128).

In the example of FIGS. 4-7, CCD 120 is a two-stage CCD (e.g., with first and second storage gates 126 and 128). This example, however, is merely illustrated. If desired, the CCD may include more than two stages.

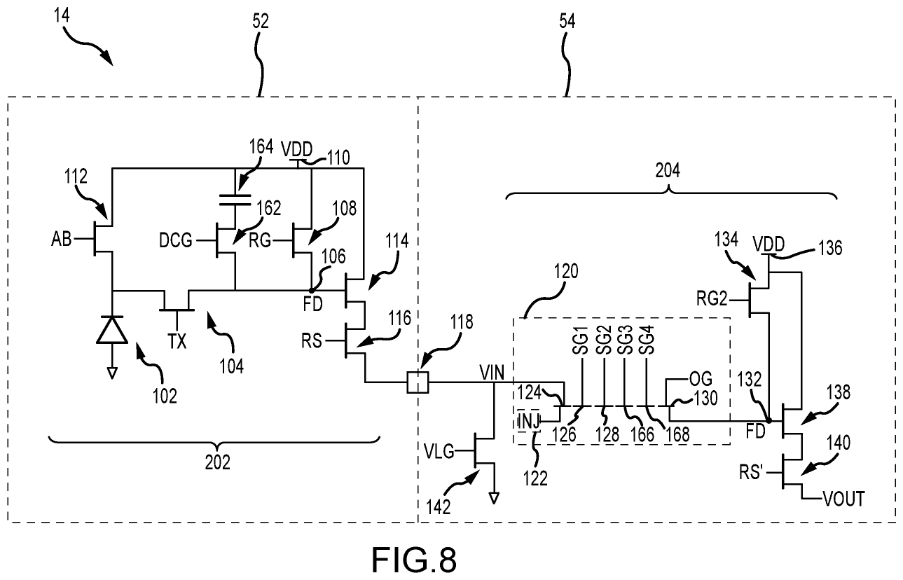

FIG. 8 is a circuit diagram of an image sensor with an imaging pixel coupled to a CCD with more than two stages. In general, each stage of the CCD allows another signal from pixel circuitry 202 to be sampled. In FIG. 4, with a two-stage CCD, two individual signals may be sampled from pixel circuitry 202 (e.g., SHS and SHR). In FIG. 8, a four-stage CCD is included. Therefore, four individual signals from pixel circuitry 202 may be stored and sampled using the CCD.

Sampling more than two signals from the pixel circuitry may be particularly useful depending upon the specific pixel circuitry design. An example of pixel circuitry is depicted in FIG. 8 where, in addition to the components previously shown and described in connection with FIG. 4, a dual conversion gain transistor and capacitor are included. Dual conversion gain transistor 162 is coupled between floating diffusion region 106 and dual conversion gain capacitor 164. Dual conversion gain transistor 162 may be used to switch the pixel circuitry between a high conversion gain mode (when the transistor is off) and a low conversion gain mode (when the transistor is on, adding the capacitance of dual conversion gain capacitor 164 to the floating diffusion region). Dual conversion gain transistor may also be used to store overflow charge from photodiode in some arrangements. This type of arrangement may increase the dynamic range of the image sensor.

Regardless of the specific arrangement of pixel circuitry 202, it may be desirable to sample and store more than two signals from pixel circuitry 202. CCD 120 in FIG. 8 includes storage gates 166 and 168 (receiving control signals SG3 and SG4, respectively) in addition to storage gates 126 and 128. These extra storage gates allow for extra samples to be stored in the analog memory CCD globally. Each sample may then be transferred to and read out from floating diffusion region 132 in substrate 54.

CCD 120 may include any desired number of gates (e.g., one, two, three, four, more than four, more than six, more than eight, more than ten, less than ten, between 1 and 5, etc.).

Storage gates may be selectively combined during operation of the image sensor if desired. For example, the CCD of FIG. 8 has four storage gates and is therefore capable of storing four discrete signals. However, in certain applications, only two discrete signals may be needed to be sampled. In this type of application, storage gates 126 and 128 may be operated in parallel and storage gates 166 and 168 may be operated in parallel. The combined storage capacity for the two discrete signals is increased in this manner (because each signal may be stored using two storage gates instead of just a single storage gate).

In FIGS. 4 and 8, an example is depicted where a single pixel 34 (e.g., pixel circuitry 202) is associated with one set of storage and readout circuitry 204. This example is merely illustrative. If desired, storage and readout circuitry 204 may be shared between multiple pixel circuits.

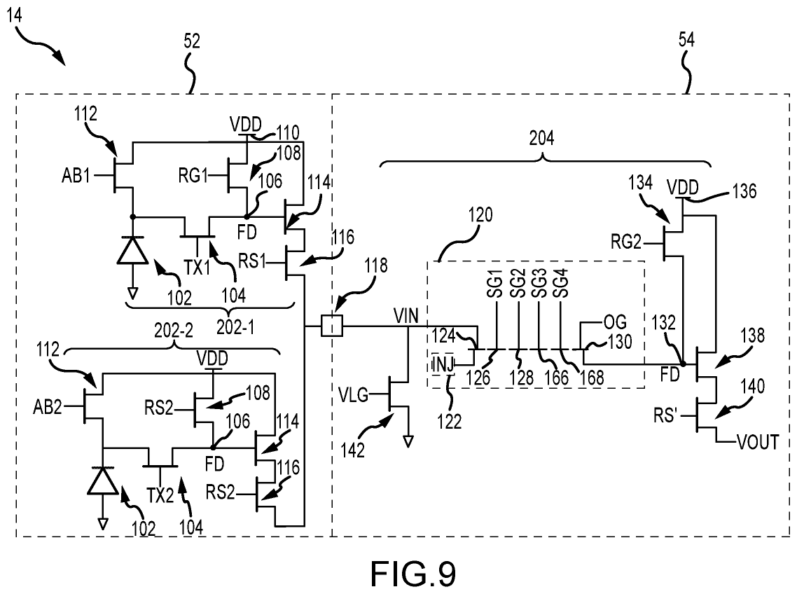

FIG. 9 is a circuit diagram of an illustrative image sensor with two pixel circuits shared between a single storage and readout circuit. As shown in FIG. 9, pixel circuitry 202-1 (with the same arrangement as in FIG. 4) is coupled to conductive interconnect 118. However, pixel circuitry 202-2 is also coupled to conductive interconnect 118 (e.g., the two pixels are coupled to a single interconnect layer). In FIG. 9, the pixel circuits are identical. However, this need not be the case and the pixel circuits may have differing arrangements if desired.

A single storage and readout circuit 204 is coupled to the conductive interconnect layer 118 for storing and reading charge from pixel circuits 202-1 and 202-2. The storage and readout circuit 204 has the same arrangement as in FIG. 8, with a four-stage CCD. The four-stage CCD may store reset and sample signals for each one of pixel circuits 202-1 and 202-2. For example, control signal RS1 (provided to row select transistor 116 in pixel circuit 202-1) may be asserted while SHR and SHS samples associated with pixel circuit 202-1 are stored in CCD 120. Control signal RS2 (provided to row select transistor 116 in pixel circuit 202-2) may be asserted while SHR and SHS samples associated with pixel circuit 202-2 are stored in CCD 120. The four signals may then be transferred out of the CCD and read out.

The example of sharing a CCD between pixels in FIG. 9 is merely illustrative. In general, there are many possible ways to share components within the image sensor. The example of two pixel circuits sharing a single storage and readout circuit is merely illustrative. In other arrangements, other numbers of pixel circuits may share a single storage and readout circuit (e.g., two, three, four, more than four, more than eight, more than sixteen, etc.). Storage gates may be added to the analog memory CCD to accommodate the additional shared pixel circuits.

Additionally or instead of sharing pixel circuits between a single CCD, CCDs may share a single source follower transistor. For example, multiple analog memory CCDs (e.g., two, three, four, more than four, more than eight, more than sixteen, etc.) may have output gates coupled to a common floating diffusion region and source follower transistor.

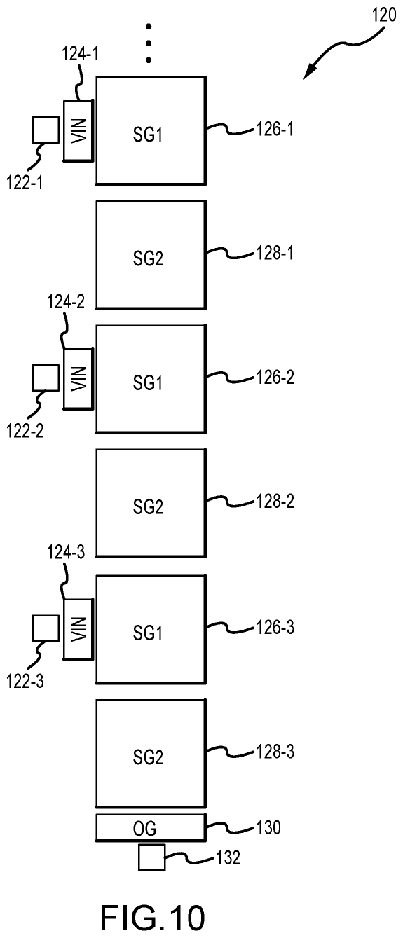

Another possible sharing arrangement for the image sensor is shown in FIG. 10. FIG. 10 is a top view showing how a single CCD with different injection points may use a single output gate and floating diffusion region. As shown, storage gates 126-1 and 128-1 may be associated with a first pixel circuit. Input gate 124-1 may be positioned between charge injector 122-1 and storage gate 126-1. Samples associated with the first pixel circuit may be stored in storage gates 126-1 and 128-1. Additionally, storage gates 126-2 and 128-2 may be associated with a second pixel circuit. Input gate 124-2 may be positioned between charge injector 122-2 and storage gate 126-2. Samples associated with the second pixel circuit may be stored in storage gates 126-2 and 128-2. This pattern continues with storage gates 126-3 and 128-3 being associated with a third pixel circuit. Input gate 124-3 may be positioned between charge injector 122-3 and storage gate 126-3. Samples associated with the third pixel circuit may be stored in storage gates 126-3 and 128-3.

Charge from multiple pixel circuits may therefore be stored simultaneously in a single CCD. The CCD may have a plurality of injection points, each associated with a respective pixel circuit, distributed along the CCD. This is in contrast to FIG. 8, where charge from multiple pixel circuits may be stored simultaneously in a single CCD using a single injection point. Each injection point (e.g., at input gate 124) may be coupled to a conductive interconnect layer associated with a respective pixel circuit.

The CCD is coupled to a single output gate 130 and floating diffusion region 132. Therefore, only a single source follower transistor 138, single select transistor 140, and single reset transistor 134 are required. The storage gates may be clocked to sequentially transfer each stored charge to floating diffusion region 132 for readout.

As previously mentioned, storage gates 126 and 128 of CCD 120 may be held at a negative voltage while storing charge to prevent dark current. This may be referred to as holding the storage gates in accumulation. In FIGS. 4-10, storage gate 126 is next to input gate 124. Input gate 124 isolates storage gate 126 from dark current from injection region 122. However, input gate 124 may itself be susceptible to dark current that then adds noise to the sample under storage gate 126. Input gate 124 may receive VIN as an input signal. VIN may not be a negative voltage, thus preventing input gate 124 from being placed in an accumulation state to mitigate dark current.

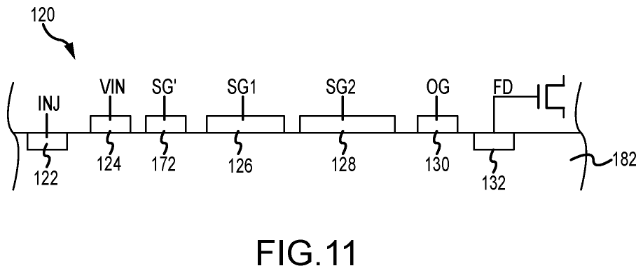

Therefore, to mitigate any noise from dark current from input gate 124, an additional gate may be interposed between input gate 124 and storage gate 126. FIG. 11 is a cross-sectional side view of CCD 120 showing injection region 122 formed in substrate 182. Input gate 124 and storage gate 126 are formed on the surface of substrate 182. Gate 172 (sometimes referred to as storage gate 172, dark-current-mitigating gate 172, supplemental gate 172, etc.) is interposed between input gate 124 and storage gate 126. Gate 172 receives a control signal SG′, which may be a negative voltage that mitigates dark current. In this way, the charge stored under storage gate 126 may be insulated from any sources of dark current. Any of the analog memory CCDs herein (e.g., in FIGS. 4-10) may optionally have additional gate 172 between input gate 124 and storage gate 126.

It should be reiterated that the arrangement of the pixel circuitry shown herein (e.g., in FIGS. 4, 8, and 9) is merely illustrative. In general, the pixel circuitry in any of the aforementioned arrangements may include an anti-blooming transistor, a dual conversion gain transistor, a dual conversion gain capacitor, one or more overflow capacitors, one or more overflow transistors, one or more charge storage regions in addition to the floating diffusion region, etc. Similarly, the example of an analog memory CCD being incorporated into a stacked chip image sensor is merely illustrative. If desired, an image sensor without stacked substrates may also include an analog memory CCD.

It should be noted that, if desired, the dopant types described herein may be reversed. For example, n-type dopants may be switched with p-type dopants and p-type dopants may be switched with n-type dopants. In general, the pixels may accumulate electrons or holes as desired.

The foregoing is merely illustrative of the principles of this invention and various modifications can be made by those skilled in the art. The foregoing embodiments may be implemented individually or in any combination.

What is claimed is:

1. An image sensor comprising:
a photodiode;
a first floating diffusion region;
a transfer transistor that is configured to transfer charge from the photodiode to the first floating diffusion region;
a source follower transistor having a gate coupled to the first floating diffusion region;
an analog memory charge coupled device that includes an input gate that is coupled to the source follower transistor, at least one storage gate, and an output gate; and
a second floating diffusion region, wherein the output gate is configured to transfer charge from the analog memory charge coupled device to the second floating diffusion region.

2. The image sensor defined in claim 1, further comprising:
a row select transistor coupled between the source follower transistor and the input gate of the analog memory charge coupled device.

3. The image sensor defined in claim 1, wherein the analog memory charge coupled device comprises a charge injector.

4. The image sensor defined in claim 3, wherein the input gate is interposed between the charge injector and the at least one storage gate.

5. The image sensor defined in claim 4, wherein the at least one storage gate comprises first and second storage gates that are configured to store first and second respective samples associated with respective charge levels of the first floating diffusion region.

6. The image sensor defined in claim 4, wherein the at least one storage gate comprises first, second, third, and fourth storage gates that are configured to store first, second, third, and fourth respective samples associated with respective charge levels of the first floating diffusion region.

7. The image sensor defined in claim 1, wherein the source follower transistor is a first source follower transistor, wherein the gate is a first gate, and wherein the image sensor further comprises:
a second source follower transistor having a second gate that is coupled to the second floating diffusion region.

8. The image sensor defined in claim 1, further comprising:
a first reset transistor coupled to the first floating diffusion region; and
a second reset transistor coupled to the second floating diffusion region.

9. The image sensor defined in claim 1, further comprising:
a first semiconductor substrate, wherein the photodiode, first floating diffusion region, transfer transistor, and source follower transistor are formed in the first semiconductor substrate; and
a second semiconductor substrate, wherein the analog memory charge coupled device and the second floating diffusion region are formed in the second semiconductor substrate.

10. The image sensor defined in claim 9, further comprising:
a conductive interconnect layer that is coupled between the source follower transistor in the first semiconductor substrate and the input gate in the second semiconductor substrate.

11. The image sensor defined in claim 1, further comprising:
a first row select transistor coupled between the source follower transistor and the input gate of the analog memory charge coupled device;
an additional photodiode;
a third floating diffusion region;
an additional transfer transistor that is configured to transfer charge from the additional photodiode to the third floating diffusion region;
an additional source follower transistor having an additional gate coupled to the third floating diffusion region; and
a second row select transistor coupled between the additional source follower transistor and the input gate of the analog memory charge coupled device.

12. The image sensor defined in claim 1, wherein the input gate is a first input gate that is interposed between the first storage gate and a first charge injector and wherein the analog memory charge coupled device further comprises a second input gate that is interposed between the second storage gate and a second charge injector.

13. The image sensor defined in claim 12, further comprising:
an additional photodiode;
a third floating diffusion region;
an additional transfer transistor that is configured to transfer charge from the additional photodiode to the third floating diffusion region; and
an additional source follower transistor having an additional gate that is coupled to the third floating diffusion region, wherein the second input gate is coupled to the additional source follower transistor.

14. An image sensor comprising:
a photodiode;
a first floating diffusion region that is coupled to the photodiode and that is configured to store charge;
a source follower transistor having a gate coupled to the first floating diffusion region;
a charge coupled device that is coupled to the source follower transistor and that is configured to store at least one charge sample that is correlated to the charge at the first floating diffusion region; and
a second floating diffusion region, wherein the charge coupled device is configured to transfer the at least one charge sample to the second floating diffusion region.

15. The image sensor defined in claim 14, further comprising:
a first semiconductor substrate, wherein the photodiode, the first floating diffusion region, and the source follower transistor are formed in the first semiconductor substrate; and
a second semiconductor substrate, wherein the charge coupled device and the second floating diffusion region are formed in the second semiconductor substrate.

16. The image sensor defined in claim 15, wherein the charge coupled device comprises a diffusion region configured to receive a charge injection voltage, at least first and second storage gates, a supplemental gate, an input gate interposed between the diffusion region and the supplemental gate, and an output gate interposed between the second storage gate and the second floating diffusion region.

17. The image sensor defined in claim 16, further comprising:
a conductive interconnect layer coupled between the first and second semiconductor substrates, wherein the conductive interconnect layer is electrically connected to the source follower transistor in the first semiconductor substrate and to the input gate in the second semiconductor substrate.

18. An image sensor comprising:
a first semiconductor substrate;
a first photodiode formed in the first semiconductor substrate;
a first floating diffusion region formed in the first semiconductor substrate and coupled to the first photodiode;
a first source follower transistor in the first semiconductor substrate having a first gate coupled to the first floating diffusion region;
a second semiconductor substrate;
a second floating diffusion region in the second semiconductor substrate; and
a charge coupled device in the second semiconductor substrate that is coupled between the first source follower transistor and the second floating diffusion region.

19. The image sensor defined in claim 18, further comprising:
a second source follower transistor in the second semiconductor substrate having a second gate coupled to the second floating diffusion region.

20. The image sensor defined in claim 19, further comprising:
a first reset transistor in the first semiconductor substrate that is coupled to the first floating diffusion region;
a first row select transistor in the first semiconductor substrate that is coupled between the first source follower transistor and the charge coupled device;
a second reset transistor in the second semiconductor substrate that is coupled to the second floating diffusion region; and
a second row select transistor in the second semiconductor substrate that is coupled to the second source follower transistor.
